(19) United States
(12) Patent Application Publication
(10) Pub. No.: US 2025/0361604 A1
(43) Pub. Date: Nov. 27, 2025

(54) FILM FORMING METHOD AND SUBSTRATE PROCESSING APPARATUS

(71) Applicant: Tokyo Electron Limited, Tokyo (JP)

(72) Inventors: Ryota IFUKU, Nirasaki-shi (JP); Masataka TOIYA, Nirasaki-shi (JP); Takashi MATSUMOTO, Nirasaki-shi (JP)

(21) Appl. No.: 19/289,166

(22) Filed: Aug. 4, 2025

Related U.S. Application Data
(63) Continuation of application No. PCT/JP2024/001937, filed on Jan. 24, 2024.

(30) Foreign Application Priority Data
Feb. 7, 2023 (JP) 2023-016583

(51) Int. Cl. C23C 16/26; C23C 16/44; C23C 16/455; C23C 16/52; H01J 37/32

(52) U.S. Cl. CPC C23C 16/26; C23C 16/4405; C23C 16/45523; C23C 16/52; H01J 37/32192; H01J 2237/3321; H01J 2237/335

(57) ABSTRACT

A film forming method of forming a carbon film includes: a) cleaning an interior of a processing container using plasma generated by supplying an oxygen-containing gas, in a state where a substrate is not present in the processing container; b) performing a first degassing in the interior of the processing container using plasma generated by supplying a first reactive gas, in a state where the substrate is not present in the processing container; c) performing a second degassing in the interior of the processing container using plasma generated by supplying a noble gas, in a state where the substrate is not present in the processing container; d) loading the substrate into the processing container; e) forming the carbon film on the substrate using plasma generated by supplying a carbon-containing gas; and f) repeating a) to e) in this order.

### CROSS-REFERENCE TO RELATED APPLICATION

This application is a bypass continuation application of international application No. PCT/JP2024/001937 having an international filing date of Jan. 24, 2024 and designating the United States, the international application being based upon and claiming the benefit of priority from Japanese Patent Application No. 2023-016583, filed on Feb. 7, 2023, the entire contents of which are incorporated herein by reference.

### TECHNICAL FIELD

The present disclosure relates to a film forming method and a substrate processing apparatus.

### BACKGROUND

Patent Document 1 discloses a film forming method of forming a carbon film using a plasma chemical vapor deposition (CVD) apparatus, the method including a step of cleaning the interior of a processing container with an oxygen-containing plasma in a state where no substrate is present in the processing container, a subsequent step of extracting and removing oxygen from the interior of the processing container with the plasma in a state where no substrate is present in the processing container, and a subsequent step of loading a substrate into the processing container to form a carbon film on the substrate by plasma CVD, wherein the cleaning step, the oxygen extraction and removal step, and the film formation step are repeatedly performed.

### PRIOR ART DOCUMENTS

### Patent Documents

Patent Document 1: Japanese laid-open publication No. 2021-105199

### SUMMARY

According to one embodiment of the present disclosure, there is provided a film forming method of forming a carbon film includes: a) cleaning an interior of a processing container using plasma generated by supplying an oxygen-containing gas, in a state where a substrate is not present in the processing container; b) performing a first degassing in the interior of the processing container using plasma generated by supplying a first reactive gas, in a state where the substrate is not present in the processing container; c) performing a second degassing in the interior of the processing container using plasma generated by supplying a noble gas, in a state where the substrate is not present in the processing container; d) loading the substrate into the processing container; e) forming the carbon film on the substrate using plasma generated by supplying a carbon-containing gas; and f) repeating a) to e) in this order.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic cross-sectional view illustrating an example of a film forming apparatus according to one embodiment of the present disclosure.

FIG. 2 is a graph illustrating an example of emission intensity during degassing using H₂ plasma.

FIG. 3 is a graph illustrating an example of emission intensity during degassing using N₂ plasma.

FIG. 4 is a graph illustrating an example of emission intensity during second-stage degassing.

FIG. 5 is a graph illustrating an example of a time-dependent change in nitrogen-related emission peak intensity.

FIG. 6 is a graph illustrating an example of a time-dependent change in nitrogen-related emission peak intensity.

FIG. 7 is a flowchart illustrating an example of a film forming method according to the present embodiment.

FIG. 8 is a diagram illustrating an example of experimental results in the present embodiment.

FIG. 9 is a diagram illustrating an example of experimental results in the present embodiment.

FIG. 10A is a diagram illustrating an example of experimental results when an additive gas is supplied in the present embodiment.

FIG. 10B is a diagram illustrating an example of experimental results when an additive gas is supplied in the present embodiment.

FIG. 11 is a diagram illustrating an example of experimental results when an additive gas is supplied in the present embodiment.

FIG. 12 is a diagram illustrating an example of experimental results when an additive gas is supplied in the present embodiment.

FIG. 13 is a flowchart illustrating an example of a film forming method according to Modification 1.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of a film forming method and a substrate processing apparatus disclosed herein will be described in detail with reference to the drawings. In addition, the disclosed technique is not limited by the following embodiments.

In carbon film formation by plasma CVD, oxygen plasma cleaning is employed as dry cleaning for removing carbon by-products out of a chamber. In the case where a continuous film formation while replacing a substrate is performed after oxygen plasma cleaning, residual oxygen that is physically or chemically adsorbed inside the chamber may desorb, potentially oxidizing the surface of the newly loaded substrate. To address this issue, it is conceivable to perform degassing, before substrate loading, to remove oxygen mainly in the form of H₂O using plasma generated from an H₂ gas, thereby preventing oxidation of the substrate surface. Further, it is conceivable to perform degassing, before substrate loading, to remove oxygen mainly in the form of N₂O using plasma generated from an N₂ gas, thereby performing faster degassing compared to plasma generated from an H₂ gas. Furthermore, it is conceivable to perform, after removing residual oxygen out of the chamber using Ar—H₂ plasma, additional oxygen removal and nitrogen termination of the chamber inner wall using plasma generated from an N₂ gas. However, when using plasma generated from an H₂ gas, there is a risk of particles being generated from the chamber inner wall. Further, when using plasma generated from an N₂ gas, cumulative film formation may lead to variations in film thickness uniformity between substrates. Therefore, there is a need to prevent both the generation of particles and variations in film thickness uniformity between substrates during cumulative film formation.

### [Configuration of Film Forming Apparatus 1]

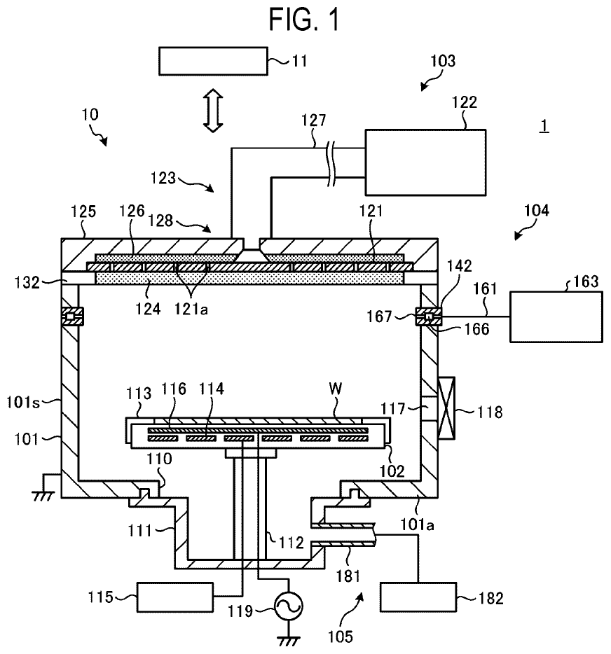

FIG. 1 is a schematic cross-sectional view illustrating an example of a film forming apparatus according to one embodiment of the present disclosure. The film forming apparatus 1 illustrated in FIG. 1 is configured, for example, as a plasma processing apparatus of an RLSA® microwave plasma type. In addition, the film forming apparatus 1 is an example of a substrate processing apparatus.

The film forming apparatus 1 includes an apparatus main body 10 and a controller 11 that controls the apparatus main body 10. The apparatus main body 10 includes a chamber 101, a stage 102, a microwave introducer 103, a gas supply mechanism 104, and an exhauster 105.

The chamber 101 is formed in an approximately cylindrical shape, and an opening 110 is formed at an approximately central portion of a bottom wall 101a of the chamber 101. The bottom wall 101a is provided with an exhaust chamber 111, which communicates with the opening 110 and protrudes downward. An opening 117, through which a substrate (hereinafter also referred to as “wafer”) W passes, is formed through a sidewall 101s of the chamber 101. The opening 117 is opened or closed by a gate valve 118. In addition, the chamber 101 is an example of a processing container. Further, a protective film such as alumina (Al₂O₃) or yttria (Y₂O₃) is formed on the inner surfaces of the sidewall 101s and the bottom wall 101a of the chamber 101.

The substrate W, which is a processing target, is placed on the stage 102. The stage 102 has an approximately disc shape and is made of ceramics such as AlN. The stage 102 is supported by a cylindrical support member 112 made of ceramics such as AlN, which extends upward from approximately the bottom center of the exhaust chamber 111. An edge ring 113 is provided on the outer edge of the stage 102 so as to surround the substrate W placed on the stage 102. Further, lift pins (not illustrated) for raising or lowering the substrate W are provided in the interior of the stage 102 so as to be able to protrude from or retract to the upper surface of the stage 102.

Furthermore, a resistive heating type heater 114 is embedded in the interior of the stage 102. The heater 114 heats the substrate W placed on the stage 102 by power supplied from a heater power supply 115. Further, a thermocouple (not illustrated) is inserted into the stage 102, so that the temperature of the substrate W is controllable, for example, to 350 to 850 degrees C. based on a signal from the thermocouple. Furthermore, an electrode 116, which has approximately the same size as the substrate W, is embedded above the heater 114 inside the stage 102, and a bias power supply 119 is electrically connected to the electrode 116. The bias power supply 119 supplies a predetermined frequency and magnitude of bias power to the electrode 116. The bias power supplied to the electrode 116 draws ions into the substrate W placed on the stage 102. In addition, the bias power supply 119 may be omitted according to plasma processing characteristics.

The microwave introducer 103 is provided on the top of the chamber 101, and includes an antenna 121, a microwave output part 122, and a microwave transmitter 123. The antenna 121 has a plurality of slots 121a, which are through-holes. The microwave output part 122 outputs microwaves. The microwave transmitter 123 guides the microwaves output from the microwave output part 122 to the antenna 121.

A dielectric window 124 made of dielectrics is provided below the antenna 121. The dielectric window 124 is supported by a support member 132, which is provided in a ring shape on the top of the chamber 101. A wave delay plate 126 is provided on the antenna 121. A shield member 125 is provided on the antenna 121. A flow path (not illustrated) is provided in the interior of the shield member 125. The shield member 125 is used to cool the antenna 121, the dielectric window 124, and the wave delay plate 126 by a fluid such as water flowing through the flow path.

The antenna 121 is made of, for example, a copper plate or aluminum plate with a surface plated in silver or gold, and the plurality of slots 121a for microwave radiation is arranged in a predetermined pattern. The arrangement pattern of the slots 121a is appropriately set to ensure even microwave radiation. An example of a suitable pattern is a radial line slot pattern where a plurality of pairs of slots 121a is arranged in a concentric shape, with two slots 121a arranged in a T-shape as a pair. The length and arrangement spacing of the slots 121a are appropriately determined according to the effective wavelength (Ag) of microwaves. Further, the slots 121a may have other shapes such as a circular shape and an arc shape. Furthermore, the arrangement form of the slots 121a is not particularly limited, and the slots may be arranged, for example, in a spiral shape or radial shape, in addition to the concentric shape. The pattern of the slots 121a is appropriately set to provide microwave radiation characteristics by which desired plasma density distribution is obtained.

The wave delay plate 126 is made of dielectrics with a higher dielectric constant than vacuum, such as quartz, ceramics (Al₂O₃), polytetrafluoroethylene, and polyimide. The wave delay plate 126 has a function of reducing the wavelength of microwaves compared to that in vacuum, thus making the antenna 121 smaller in size. In addition, the dielectric window 124 is also made of similar dielectrics.

The thicknesses of the dielectric window 124 and the wave delay plate 126 are adjusted to ensure that an equivalent circuit, formed by the wave delay plate 126, the antenna 121, the dielectric window 124, and plasma, satisfies resonance conditions. Adjusting the thickness of the wave delay plate 126 enables adjustment of the phase of microwaves. By adjusting the thickness of the wave delay plate 126 to make the junction of the antenna 121 coincide with the “antinode” of standing waves, microwave reflection may be minimized and the radiative energy of microwaves may be maximized. Further, using the same material for the wave delay plate 126 and the dielectric window 124 may prevent interface reflection of microwaves.

The microwave output part 122 includes a microwave oscillator. The microwave oscillator may be of a magnetron type or a solid state type. The frequency of microwaves generated by the microwave oscillator is, for example, 300 MHz to 10 GHz. As an example, the microwave output part 122 outputs microwaves of 2.45 GHz using a magnetron-type microwave oscillator. Microwaves are an example of electromagnetic waves.

The microwave transmitter 123 includes a waveguide 127 and a coaxial waveguide 128. In addition, it may further include a mode converter. The waveguide 127 guides the microwaves output from the microwave output part 122. The coaxial waveguide 128 includes an inner conductor connected to the center of the antenna 121 and an outer conductor outside the inner conductor. The mode converter is provided between the waveguide 127 and the coaxial waveguide 128. The microwaves output from the microwave output part 122 propagate within the waveguide 127 in a TE mode, and are converted from the TE mode to a TEM mode by the mode converter. The microwaves, converted into the TEM mode, propagate to the wave delay plate 126 through the coaxial waveguide 128, and are radiated from the wave delay plate 126 into the chamber 101 through the slots 121a of the antenna 121 and the dielectric window 124. In addition, a tuner (not illustrated) is provided in the middle of the waveguide 127 to match the impedance of a load (plasma) in the chamber 101 with the output impedance of the microwave output part 122.

The gas supply mechanism 104 includes a shower ring 142 provided in a ring shape along an inner wall of the chamber 101. The shower ring 142 has a ring-shaped flow path 166 provided in the interior thereof and a plurality of discharge ports 167 connected to the flow path 166 so as to be open to the interior of the flow path 166. A gas supplier 163 is connected to the flow path 166 via a pipe 161. The gas supplier 163 is provided with a plurality of gas sources and a plurality of flow-rate controllers. In one embodiment, the gas supplier 163 is configured to supply at least one processing gas from a corresponding gas source to the shower ring 142 through a corresponding flow-rate controller. The gas supplied to the shower ring 142 is supplied into the chamber 101 from the plurality of discharge ports 167.

Further, when a graphene film is formed as an example of a carbon film on the substrate W, the gas supplier 163 supplies a carbon-containing gas, a hydrogen-containing gas, and a noble gas, which are controlled to a predetermined flow rate, into the chamber 101 through the shower ring 142. Further, the gas supplier 163 may supply an additive gas into the chamber 101 through the shower ring 142. In the present embodiment, the carbon-containing gas is, for example, a C₂H₂ gas. In addition to the acetylene (C₂H₂) gas, any one of an ethylene (C₂H₄) gas, methane (CH₄) gas, ethane (C₂H₆) gas, propane (C₃H₈) gas, propylene (C₃H₆) gas, methanol (CH₃OH) gas, and ethanol (C₂H₅OH) gas may also be used. Further, in the present embodiment, the hydrogen-containing gas is, for example, a hydrogen gas. In addition, instead of or in addition to the hydrogen gas, a halogen-based gas such as a fluorine (F₂) gas, chlorine (Cl₂) gas, or a bromine (Br₂) gas may be used. Further, in the present embodiment, the noble gas is, for example, an Ar gas. Instead of the Ar gas, another noble gas such as He gas may be used. Further, in the present embodiment, the additive gas is, for example, an oxygen gas.

The exhauster 105 includes the exhaust chamber 111, an exhaust pipe 181 provided on a sidewall of the exhaust chamber 111, and an exhaust device 182 connected to the exhaust pipe 181. The exhaust device 182 includes a vacuum pump and a pressure control valve, or the like.

The controller 11 includes a memory, which is a non-transitory computer readable storage medium, a processor, and an input/output interface. The memory stores programs executed by the processor and recipes including data such as conditions for each processing. The processor executes the programs read from the memory and controls each component of the apparatus main body 10 via the input/output interface based on the recipes stored in the memory.

For example, the controller 11 controls each component of the film forming apparatus 1 to perform a film forming method to be described later. As a detailed example, the controller 11 executes a) a step of cleaning the interior of the chamber 101 using plasma, generated by supplying an oxygen-containing gas, in a state where the substrate W is not present in the chamber 101. The controller 11 executes b) a step of performing first degassing in the interior of the chamber 101 using plasma, generated by supplying a first reactive gas, in a state where the substrate W is not present in the chamber 101. The controller 11 executes c) a step of performing second degassing in the interior of the chamber 101 using plasma, generated by supplying a noble gas, in a state where the substrate W is not present in the chamber 101. The controller 11 executes d) a step of loading the substrate W into the chamber 101. The controller 11 executes e) a step of forming a carbon film on the substrate W using plasma generated by supplying a carbon-containing gas. The controller 11 executes f) a step of repeating steps a) to e) in this order. Here, the first reactive gas may be at least one of a hydrogen (H₂) gas and nitrogen (N₂) supplied from the gas supplier 163. Further, the noble gas may be an argon (Ar) gas supplied from the gas supplier 163. Further, the carbon-containing gas may be an acetylene (C₂H₂) gas supplied from the gas supplier 163. Further, the carbon-containing gas is not limited to acetylene. For example, it may be any one of an ethylene (C₂H₄) gas, methane (CH₄) gas, ethane (C₂H₆) gas, propane (C₃H₈) gas, propylene (C₃H₆) gas, methanol (CH₃OH) gas, and ethanol (C₂H₅OH) gas. Further, an additive gas may be supplied in step b) and/or step e). The additive gas may be, for example, an oxygen (O₂) gas.

### [Details of Degassing]

Next, details of degassing will be described. In addition, in the following description, plasma generated from an H₂ gas may be simply referred to as “H₂ plasma”, and plasma generated from an N₂ gas may be simply referred to as “N₂ plasma”.

As described above, in degassing using H₂ plasma, residual oxygen in the chamber 101 is removed as H₂O. However, since the vapor pressure of H₂O is low, degassing takes time. In contrast, in degassing using N₂ plasma, residual oxygen in the chamber 101 is removed as N₂O, which has a higher vapor pressure, allowing degassing to be completed within a shorter time. For example, at 100 degrees C., the vapor pressure of H₂O is 1 atm (1013 hPa), whereas the vapor pressure of N₂O is 200 atm (20.16 MPa), which is more than two orders of magnitude higher.

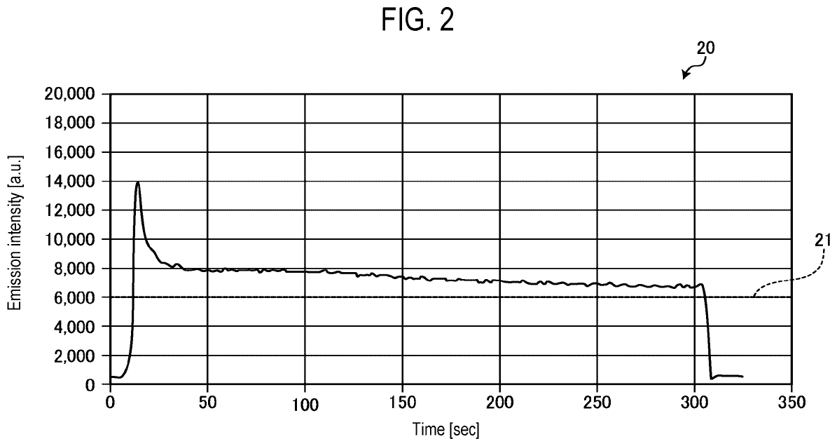

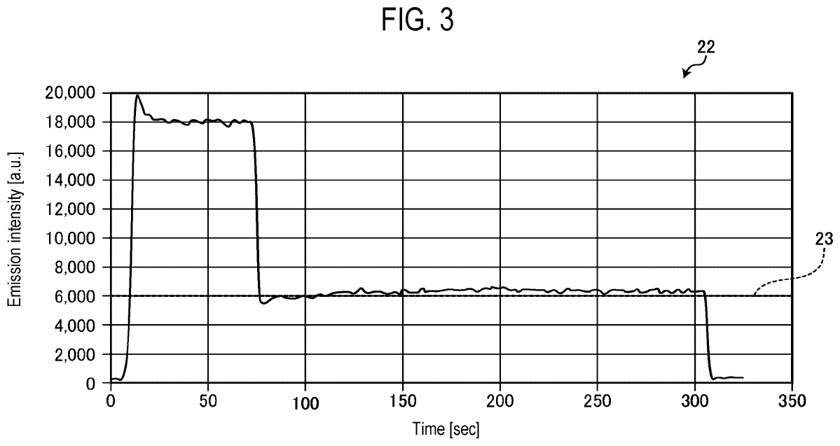

Next, degassing using H₂ plasma and degassing using N₂ plasma will be compared with reference to FIGS. 2 and 3. FIG. 2 is a graph illustrating an example of emission intensity during degassing using H₂ plasma. Graph 20 illustrated in FIG. 2 represents the emission intensity of OH (=308.9 nm) measured by an optical emission spectrometer (OES) during degassing using H₂ plasma. In addition, the emission intensity of OH is used as an indicator of residual oxygen. In graph 20, the vertical axis represents emission intensity [a.u.] in arbitrary units, and the horizontal axis represents processing time [seconds]. Further, line 21 represents the background value (6000) of the emission intensity of OH. As illustrated in graph 20, it can be seen that in degassing using H₂ plasma, a peak appears immediately after the start of processing, but the intensity does not decrease to the background value even after 300 seconds, exhibiting a so-called tailing state, and residual oxygen has not been completely removed.

FIG. 3 is a graph illustrating an example of emission intensity during degassing using N₂ plasma. Graph 22 illustrated in FIG. 3 represents the emission intensity of OH measured by an OES during degassing using N₂ plasma. Further, in graph 22, to verify degassing using N₂ plasma, H₂ plasma is used to confirm the presence of residual oxygen after degassing using N₂ plasma is performed for 60 seconds. In graph 22, the vertical axis represents emission intensity [a.u.] in arbitrary units, and the horizontal axis represents processing time [seconds]. Further, line 23 represents the background value (6000) of the emission intensity of OH in H₂ plasma. As illustrated in graph 22, the background emission intensity is high due to reactions with residual hydrogen during degassing using N₂ plasma up to 60 seconds. After switching to H₂ plasma for verification, the emission intensity of OH drops to the background value represented by line 23 at the switching time point. In other words, it can be seen that degassing using N₂ plasma completes the removal of residual oxygen within 60 seconds. In addition, in graph 22, degassing using N₂ plasma is performed for 60 seconds, but the removal of residual oxygen could be completed even at 30 seconds. It can be seen from FIGS. 2 and 3 that degassing using N₂ plasma may shorten the processing time compared to degassing using H₂ plasma.

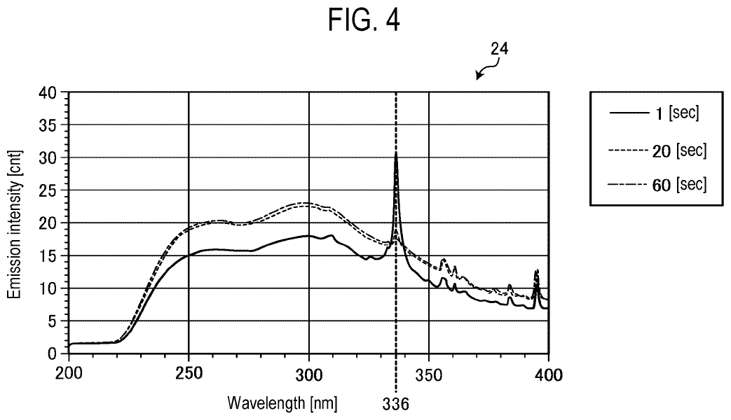

Next, the case where, after first-stage degassing using N₂ plasma, second-stage degassing using H₂ plasma or Ar plasma is performed will be described with reference to FIGS. 4 to 6. In addition, the first-stage degassing aims to remove oxygen, whereas the second-stage degassing aims to remove nitrogen. Further, plasma of a mixed gas of N₂ gas and Ar gas is used in the first-stage degassing. Furthermore, a mixed gas of H₂ gas and Ar gas is used in the second-stage degassing using H₂ plasma, whereas only Ar gas is used in the second-stage degassing using Ar plasma.

FIG. 4 is a graph illustrating an example of emission intensity during second-stage degassing. Graph 24 illustrated in FIG. 4 shows the emission intensity measured by an OES during second-stage degassing using H₂ plasma. In graph 24, the vertical axis represents emission intensity [cnt] in count units, and the horizontal axis represents wavelength [nm]. In graph 24, when focusing on nitrogen-related wavelengths such as around 336 nm for NH, the largest peak occurs at 1 second immediately after the start of processing, and the peak decreases with time at 20 seconds and 60 seconds. That is, in graph 24, denitrification in the chamber 101 is in progress.

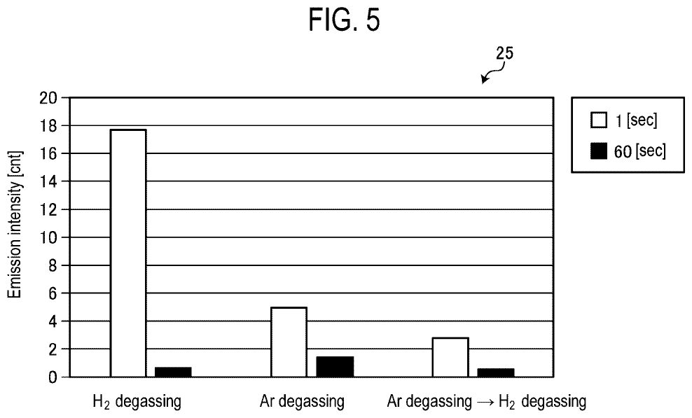

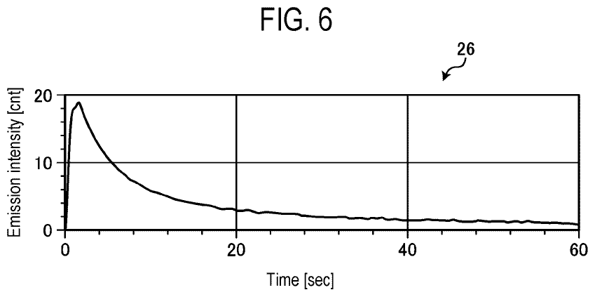

FIGS. 5 and 6 are graphs illustrating an example of a time-dependent change in nitrogen-related emission peak intensity. Graph 25 illustrated in FIG. 5 shows, as second-stage degassing, degassing using H₂ plasma, degassing using Ar plasma, and degassing using H₂ plasma after degassing using Ar plasma (60 seconds). In addition, in graph 25, degassing using H₂ plasma is denoted as “H₂ degassing,” and degassing using Ar plasma is denoted as “Ar degassing.” In graph 25, the vertical axis represents emission intensity [cnt] in count units, and the horizontal axis represents values side by side at 1 second (start of processing) and 60 seconds for each degassing. Graph 25 of degassing using H₂ plasma corresponds to around 336 nm for NH in graph 24 of FIG. 4.

It can be seen that in the case of degassing using H₂ plasma, the emission intensity decreases from 17.8 cnt at 1 second to 0.6 cnt at 60 seconds, indicating sufficient progress in denitrification. Further, graph 26 illustrated in FIG. 6 shows a time-dependent change in degassing using H₂ plasma in graph 25. In addition, the count values of the emission intensity in graphs 25 and 26 are values obtained by subtracting background values from the count values of graph 24.

In the case of degassing using Ar plasma in graph 25, the emission intensity decreases from 5 cnt at 1 second to 1.4 cnt at 60 seconds, indicating that physical denitrification progresses with Ar plasma as well, but is not complete at 60 seconds. In addition, sufficient progress in denitrification may be achieved by extending the processing time of degassing using Ar plasma.

It can be seen that in the case where degassing using H₂ plasma is performed after degassing using Ar plasma (60 seconds) in graph 25, the emission intensity decreases from 2.8 cnt at 1 second to 0.5 cnt at 60 seconds, indicating that the denitrification that was incomplete with Ar plasma alone is sufficiently progressed. In other words, even after degassing using Ar plasma, subsequent chemical degassing using H₂ plasma enables more efficient progress in denitrification.

### [Film Forming Method]

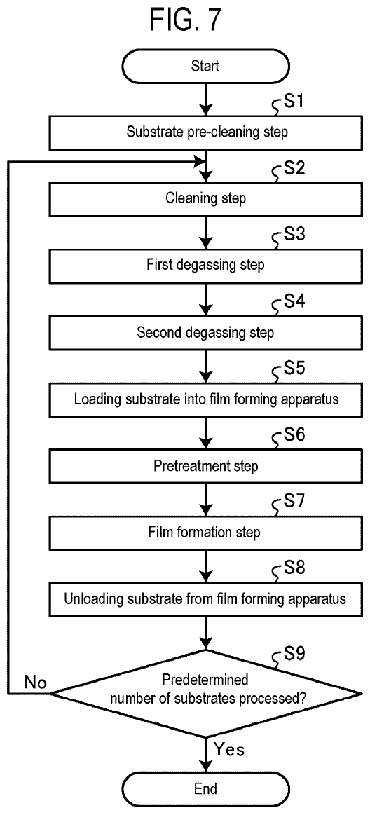

Next, a film forming method according to the present embodiment will be described. FIG. 7 is a flowchart illustrating an example of a film forming method according to the present embodiment.

In the film forming method according to the present embodiment, first, in a processing apparatus (not illustrated), a controller of the processing apparatus executes a pre-cleaning step on the substrate W (step S1). The pre-cleaning step is, for example, plasma processing to remove, e.g., an oxide film on the surface of the substrate W. In addition, the pre-cleaning step may be omitted.

The controller 11 of the film forming apparatus 1 executes a cleaning step for cleaning the interior of the chamber 101 in a state where the substrate W is not present in the chamber 101 (step S2). The controller 11 controls the gate valve 118 to open the opening 117. A dummy wafer is loaded into the processing space of the chamber 101 through the opening 117 while the opening 117 is open, and is placed on the stage 102. The controller 11 then controls the gate valve 118 to close the opening 117.

The controller 11 controls the gas supplier 163 to supply a cleaning gas from the plurality of discharge ports 167 to the chamber 101, thereby cleaning a carbon film such as an amorphous carbon film adhered to the inner wall of the chamber 101. In addition, an O₂ gas may be used as the cleaning gas, but an oxygen-containing gas such as CO gas or CO₂ gas may also be used. Further, the cleaning gas may also contain a noble gas such as Ar gas. Further, the dummy wafer may be omitted. In addition, the cleaning step may be performed for each film formation conducted on a plurality of substrates W.

After completion of the cleaning step, the controller 11 executes a first degassing step for removing residual oxygen (step S3). The controller 11 controls the gas supplier 163 to supply a first reactive gas from the plurality of discharge ports 167 to the chamber 101. Further, the controller 11 controls the exhauster 105 to control the internal pressure of the chamber 101 to a predetermined pressure (e.g., 50 mTorr to 1 Torr (6.67 Pa to 133 Pa). As the first reactive gas in the first degassing step, for example, an H₂ gas, an N₂ gas, or a mixed gas of these, or a mixed gas of these with an Ar gas may be used. Further, another noble gas such as He gas may be used instead of Ar gas. In addition, the flow rate ratio of the H₂ gas to the N₂ gas in the first reactive gas may be, for example, 1:1000 to 1000:1. Further, the flow rate ratio of the first reactive gas to the noble gas in the first degassing step may be, for example, 1:1000 to 1000:1. Further, in addition to the first reactive gas, an additive gas may also be supplied in the first degassing step. As the additive gas in the first degassing step, for example, an oxygen (O₂) gas may be used. The flow rate ratio of the first reactive gas to the additive gas in the first degassing step may be, for example, 1:1 to 5000:1. The controller 11 controls the microwave introducer 103 to ignite plasma by microwaves with a predetermined power (e.g., 100 W to 2500 W). The controller 11 executes the first degassing step using plasma of the first reactive gas for a predetermined time (e.g., 30 seconds to 180 seconds). In the first degassing step, oxidizing components such as O₂ and H₂O remaining in the chamber 101 are chemically discharged as O-containing radicals. In other words, the first degassing step is a process that extracts and removes oxygen from the interior of the chamber 101. Further, by supplying the additive gas together with the first reactive gas, excessive reduction that may generate aluminum (Al) or yttrium (Y) from a protective film can be prevented, and physicochemical etching can be prevented, thereby preventing the occurrence of metal contamination. In addition, the dummy wafer may be omitted in the first degassing step.

After completion of the first degassing step, the controller 11 executes a second degassing step for removing nitrogen (step S4). The controller 11 controls the gas supplier 163 to supply a noble gas from the plurality of discharge ports 167 to the chamber 101. Further, the controller 11 controls the exhauster 105 to control the internal pressure of the chamber 101 to a predetermined pressure (e.g., 50 mTorr to 1 Torr). As the noble gas in the second degassing step, for example, an He gas or Ar gas may be used. The controller 11 controls the microwave introducer 103 to ignite plasma by microwaves with a predetermined power (e.g., 100 W to 2500 W). The controller 11 executes the second degassing step using plasma of the noble gas for a predetermined time (e.g., 30 seconds to 180 seconds). In the second degassing step, nitrogen components such as N₂ and NH remaining in the chamber 101 are physically discharged. In other words, the second degassing step is a process that extracts and removes nitrogen from the interior of the chamber 101. Further, the second degassing step prevents the generation of particles. In addition, the dummy wafer may be omitted in the second degassing step.

After completion of the second degassing step, the controller 11 stops the supply of the microwaves to stop the generation of plasma. After completion of the second degassing step, the controller 11 controls the gate valve 118 to open the opening 117. When a dummy wafer is used in the second degassing step, the dummy wafer is unloaded from the chamber 101 by an arm of a transport chamber (not illustrated) through the opening 117 while the opening 117 is open. The substrate W is loaded into the processing space of the chamber 101 through the opening 117 while the opening 117 is open, and is placed on the stage 102. In other words, the controller 11 controls the apparatus main body 10 to load substrate W into the chamber 101 (step S5). The controller 11 then controls the gate valve 118 to close the opening 117.

The controller 11 controls the exhauster 105 to reduce the internal pressure of the chamber 101 to a predetermined pressure (e.g., 50 mTorr to 1 Torr). The controller 11 controls the gas supplier 163 to supply a hydrogen-containing gas and a carbon-containing gas, which are plasma generation gases, from the discharge ports 167 to the chamber 101. In addition, the hydrogen-containing gas contains a hydrogen (H₂) gas and an inert gas (Ar gas). Further, the carbon-containing gas is a gas containing a hydrocarbon gas represented by CₓH_{y} (x and y are natural numbers), for example, C₂H₂ gas. Further, the controller 11 controls the microwave introducer 103 to ignite plasma by microwaves of a predetermined power (e.g., 100 W to 1500 W). The controller 11 executes a pretreatment step for a predetermined time (e.g., 5 seconds to 15 minutes) using plasma of the hydrogen-containing gas and carbon-containing gas, in order to improve various surface characteristics of the substrate W (step S6). For example, the pretreatment step improves the adhesion between the surface of the substrate W and a graphene film, which is an example of a carbon film.

In addition, one or multiple gases among an H₂ gas, CₓH_{y} Gas, and Ar gas may be used as plasma generation gases. Further, in the pretreatment step, graphene film formation is not performed even if a CₓH_{y} gas is supplied. Furthermore, in the pretreatment step, annealing may be performed in addition to or instead of plasma processing. When annealing is performed, the internal pressure of the chamber 101 is reduced to a predetermined pressure (e.g., 50 mTorr to 1 Torr), and, for example, a hydrogen-containing gas is supplied to the chamber 101. Further, the pretreatment step may be omitted.

After completion of the pretreatment step, the controller 11 stops the supply of the microwaves to stop the generation of plasma. Further, the controller 11 controls the exhauster 105 to control the internal pressure of the chamber 101 to a predetermined pressure (e.g., 1 mTorr to 1 Torr (0.133 Pa 133 Pa). The controller 11 controls the heater power supply 115 to heat the substrate W to a predetermined temperature (e.g., 300 to 500 degrees C.). The controller 11 controls the gas supplier 163 to supply a hydrogen-containing gas and a carbon-containing gas, which are plasma generation gases, from the discharge ports 167 to the chamber 101. In addition, the hydrogen-containing gas contains a hydrogen (H₂) gas and an inert gas (Ar gas). Further, an inert gas may be used as a plasma generation gas instead of the hydrogen-containing gas. In addition, the carbon-containing gas is, for example, a C₂H₂ gas or C₂H₄ gas. Further, the controller 11 may control the gas supplier 163 to supply an additive gas to the chamber 101, in addition to the plasma generation gas. As the additive gas added to the plasma generation gas, for example, an oxygen (O₂) gas may be used. The flow rate ratio of the plasma generation gas to the additive gas may be, for example, 25:1 to 1000:1. Further, the controller 11 controls the microwave introducer 103 to ignite plasma at a predetermined power (e.g., 300 W to 1500 W). The controller 11 executes a film formation step for a predetermined time (e.g., 5 seconds to 15 minutes) using plasma of the hydrogen-containing gas and carbon-containing gas to from a graphene film on the substrate W (step S7). In addition, in the film formation step, a carbon film such as an amorphous carbon film or a diamond-like carbon film may be formed. In the film formation step, by supplying the additive gas together with the plasma generation gas, the film thickness of an interfacial oxide film (natural oxide film) formed on the surface (e.g., Si) of the substrate W may be reduced, and the film thickness of the carbon film may be increased.

After completion of the film formation step, the controller 11 stops the supply of the microwaves to stop the generation of plasma. Further, the controller 11 controls the gate valve 118 to open the opening 117. The controller 11 controls the apparatus main body 10 to raise the substrate W by protruding substrate support pins (not illustrated) from the upper surface of the stage 102. The substrate W is unloaded from the chamber 101 by the arm of the transport chamber (not illustrated) through the opening 117 while the opening 117 is open. In other words, the controller 11 controls the apparatus main body 10 to unload substrate W from the chamber 101 (step S8).

After unloading the substrate W from the chamber 101, the controller 11 determines whether a predetermined number of substrates W have been subjected to film formation (step S9). If the controller 11 determines that the predetermined number has not been processed (step S9: “No”), the controller 11 returns to step S2, and controls the apparatus main body 10 to execute the cleaning step, the first degassing step, and the second degassing step. Further, the controller 11 controls the apparatus main body 10 to place the next substrate W and execute the pretreatment step and the film formation step thereon. That is, the controller 11 controls the apparatus main body 10 to repeat the cleaning step, the first degassing step, the second degassing step, the step of loading the substrate W, the pretreatment step, and the film formation step. On the other hand, if the controller 11 determines that the predetermined number has been processed (step S9: “Yes”), the controller 11 ends film formation. In this way, since deoxidation is performed in the first degassing step and denitrification is performed in the second degassing step, the generation of particles and variations in film thickness uniformity between the substrates W during cumulative film formation processing may be prevented.

### [Experimental Results]

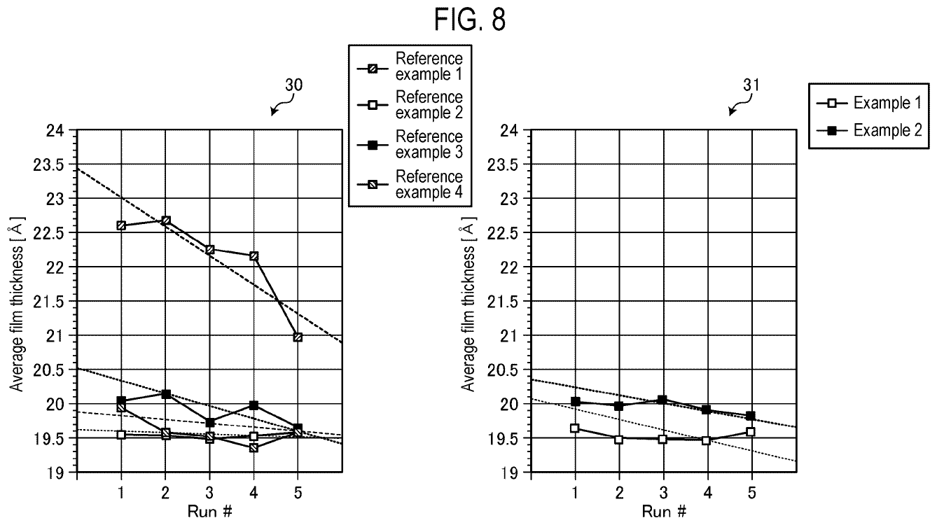

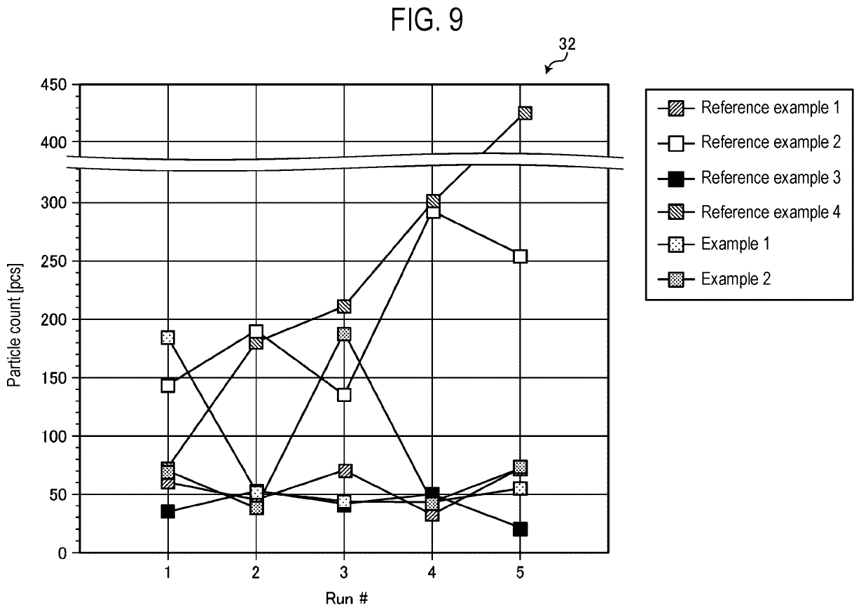

Next, experimental results in the present embodiment will be described with reference to FIGS. 8 and 9. FIGS. 8 and 9 are diagrams illustrating examples of experimental results according to the present embodiment. Graphs 30 and 31 in FIG. 8 show the transition of the average film thickness of a carbon film (graphene film) formed on the substrate W. Graphs 30 and 31 represent the number of substrates W processed as “Run #,” and show the transition of the average film thickness when five substrates W from #1 to #5 were processed. Further, the processing conditions in FIGS. 8 and 9 are as follows. Further, the gas species and flow rate used in degassing are different and will be described later.

### <Processing Conditions>

### Cleaning

Internal pressure of chamber 101:50 mTorr to 1 Torr (6.67 Pa to 133 Pa) Radio frequency power: 500 W to 2500 W

Processing gas: Ar/O₂ mixed gas

Processing time: 5 seconds to 180 seconds

### Degassing

Internal pressure of chamber 101:50 mTorr to 1 Torr (6.67 Pa to 133 Pa)

Radio frequency power: 500 W to 2500 W

Processing time: 5 seconds to 180 seconds

Pretreatment (annealing)

Internal pressure of chamber 101:50 mTorr to 1 Torr (6.67 Pa to 133 Pa)

Processing gas: Ar/H₂ mixed gas

Processing temperature: 300 to 600 degrees C.

Processing time: 5 seconds to 180 seconds

### Film Formation

Internal pressure of chamber 101:50 mTorr to 1 Torr (6.67 Pa to 133 Pa)

Radio frequency power: 500 W to 2500 W

Processing gas: Ar/C₂H₂ mixed gas

Processing time: 5 seconds to 180 seconds

Reference Example 1 in graph 30 corresponds to the case where no degassing was performed, and the equation of the approximate straight line indicating the film thickness trend from #1 to #5 was y=−0.4219x+23.852. Reference Example 2 in graph 30 corresponds to the case where a single-stage degassing was performed using an H₂/Ar mixed gas at a flow rate of 500/500 sccm, and the equation of the approximate straight line indicating the film thickness trend from #1 to #5 was y=−0.0238x+19.662. Reference Example 3 in graph 30 corresponds to the case where a single-stage degassing was performed using an N₂/Ar mixed gas at a flow rate of 500/500 sccm, and the equation of the approximate straight line indicating the film thickness trend from #1 to #5 was y=−0.1841x+20.711. Reference Example 4 in graph 30 corresponds to the case where a single-stage degassing was performed using an N₂/H₂/Ar mixed gas at a flow rate of 250/250/500 sccm, and the equation of the approximate straight line indicating the film thickness trend from #1 to #5 was y=−0.0535x+19.933.

Example 1 in graph 31 corresponds to the case where an N₂/Ar mixed gas was used at a flow rate of 500/500 sccm in a first degassing, and an Ar gas was used at a flow rate of 1000 sccm in a second degassing. In Example 1, the equation of the approximate straight line indicating the film thickness trend from #1 to #5 was y=−0.1498x+20.245. Example 2 in graph 31 corresponds to the case where an N₂/H₂/Ar mixed gas was used at a flow rate of 250/250/500 sccm in a first degassing, and an Ar gas was used at a flow rate of 1000 sccm in a second degassing. In Example 2, the equation of the approximate straight line indicating the film thickness trend from #1 to #5 was y=−0.1178x+20.497. It can be seen from graphs 30 and 31 that when the degassing using H₂/Ar mixed gas plasma or Ar gas plasma as in Reference Examples 2 and 4 and Examples 1 and 2 was performed as a final process, variations in film thickness tended to be smaller.

Graph 32 in FIG. 9 illustrates the transition of the number of particles in Reference Examples 1 to 4 and Examples 1 and 2. Similar to graphs 30 and 31, graph 32 represents the number of substrates W processed as “Run #,” and shows the transition of the number of particles when five substrates W from #1 to #5 were processed. It can be seen from graph 32 that when degassing was performed using an H₂ gas as in Reference Examples 2 and 4, the number of particles tended to increase. On the other hand, it can be seen that when degassing was performed without an H₂-containing gas as in Reference Examples 1 and 3 and Examples 1 and 2, the number of particles remained stable.

Based on graphs 30 to 32, taking into account both the average film thickness and the number of particles, it is desirable that degassing be performed such that degassing using a processing gas that includes at least one of an H₂ gas and N₂ gas is performed as a first stage, and degassing using an Ar gas as a second stage. This may prevent both the generation of particles and variations in film thickness uniformity between the substrates W during cumulative film formation.

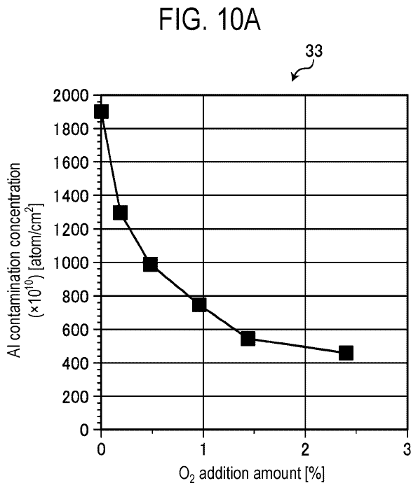

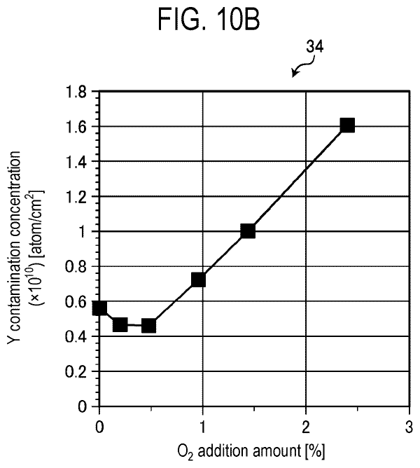

Next, experimental results concerning an additive gas in the present embodiment will be described with reference to FIGS. 10A to 12. FIGS. 10A to 12 are diagrams illustrating examples of experimental results when an additive gas is supplied in the present embodiment. Graph 33 illustrated in FIG. 10A shows the concentration of aluminum (Al) contamination when the addition amount of oxygen gas, which is an additive gas, was changed during the film formation step (step S7) for forming a carbon film (graphene film) on the substrate W according to the flow in FIG. 7. Further, graph 34 illustrated in FIG. 10B shows the concentration of yttrium (Y) contamination when the addition amount of oxygen gas, which is an additive gas, was changed during the film formation step (step S7) for forming a carbon film (graphene film) on the substrate W according to the flow in FIG. 7. In addition, in graphs 33 and 34, the horizontal axis represents the addition amount of oxygen gas (percentage), and the vertical axis represents the concentration of aluminum (Al) or yttrium (Y) contamination (× 1010) [atom/cm²].

As illustrated in graphs 33 and 34, by supplying a trace amount of additive gas together with a carbon-containing gas during the film formation step (step S7), metal contamination from a protective film on the inner surfaces of the sidewall 101s and the bottom wall 101a of the chamber 101 may be reduced. Further, the in-plane uniformity of the substrate W may be improved.

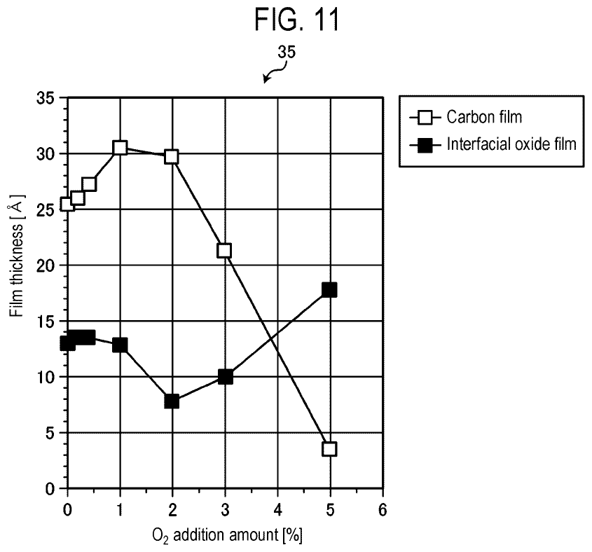

Graph 35 illustrated in FIG. 11 shows variations in the film thickness of an interfacial oxide film (natural oxide film) and a carbon film (graphene film) when the addition amount of oxygen gas, which is an additive gas, was changed during the film formation step (step S7) for forming a carbon film (graphene film) on the substrate W according to the flow in FIG. 7. In graph 35, the horizontal axis represents the addition amount of oxygen gas (percentage), and the vertical axis represents the film thicknesses of the interfacial oxide film (natural oxide film) and the carbon film (graphene film).

As illustrated in graph 35, by supplying a trace amount of additive gas together with the carbon-containing gas during the film formation step (step S7), the thickness of the interfacial oxide film (natural oxide film) can be reduced and the thickness of the carbon film (graphene film) can be increased. This may prevent variations in film thickness uniformity between the substrates W during cumulative film formation.

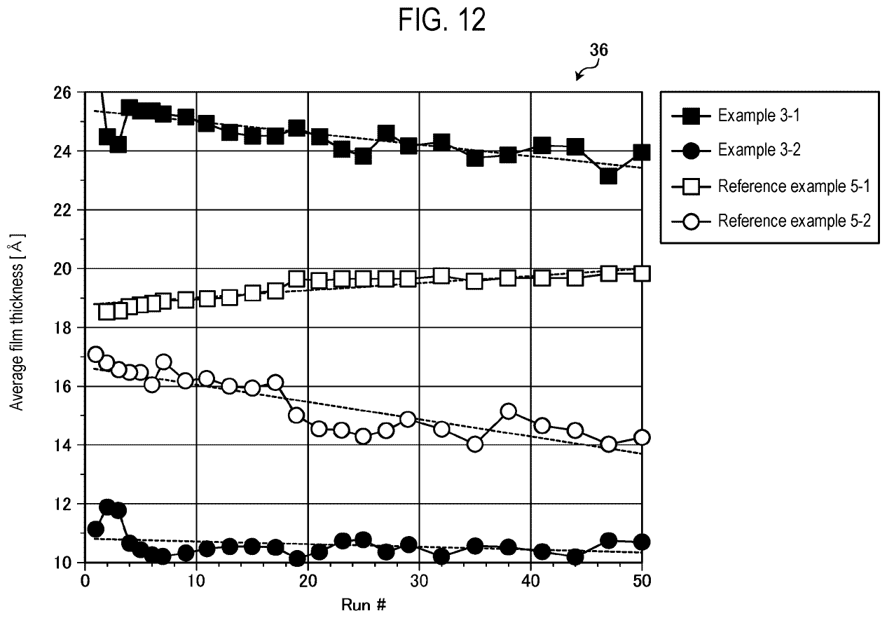

Graph 36 illustrated in FIG. 12 shows variations in the average film thickness between the substrates W when carbon films (graphene films) were consecutively formed on 50 substrate W while varying the addition amount of oxygen gas, which is an additive gas, in the film formation step (step S7) according to the flow in FIG. 7. In graph 36, the horizontal axis represents the number of substrates W processed as “Run #,” and the vertical axis represents the average film thickness of an interfacial oxide film (natural oxide film) and a carbon film (graphene film). In graph 36, variations in the average film thickness of the interfacial oxide film (natural oxide film) and the carbon film (graphene film) between the substrates W when an additive gas was supplied is presented as Example 3. Further, in graph 36, variations in the average film thickness of the interfacial oxide film (natural oxide film) and the carbon film (graphene film) between the substrates W when no additive gas was supplied is presented as Reference Example 5.

Example 3-1 in graph 36 shows the average film thickness of a carbon film (graphene film) when an 1% oxygen gas was added as an additive gas. Example 3-2 in graph 36 shows the average film thickness of an interfacial oxide film (natural oxide film) when an 1% oxygen gas was added as an additive gas. Further, Reference Example 5-1 in graph 36 shows the average film thickness of a carbon film (graphene film) when no additive gas was supplied. Reference Example 5-2 in graph 36 shows the average film thickness of an interfacial oxide film (natural oxide film) when no additive gas was supplied. In addition, in Example 3-1, the equation of the approximate straight line indicating the film thickness trend of the carbon film (graphene film) was y=−0.0397x+25.443. On the other hand, in Reference Example 5-1, the equation of the approximate straight line indicating the film thickness trend of the carbon film (graphene film) was y=0.0268x+18.726.

As illustrated in graph 36, even when continuous film formation was performed, by supplying a trace amount of additive gas together with the carbon-containing gas during the film formation step (step S7), the thickness of the interfacial oxide film (natural oxide film) can be reduced and the thickness of the carbon film (graphene film) may be increased. This may prevent variations in film thickness uniformity between the substrates W during cumulative film formation.

### [Modification 1]

In the above embodiment, degassing was performed in two stages. However, degassing may also be performed in three stages, and an embodiment in this case will be described as Modification 1. In addition, the same reference numerals will be given to the same components as those in the film forming apparatus 1 of the embodiment, and the repeated description of the same configurations and operations thereof will be omitted.

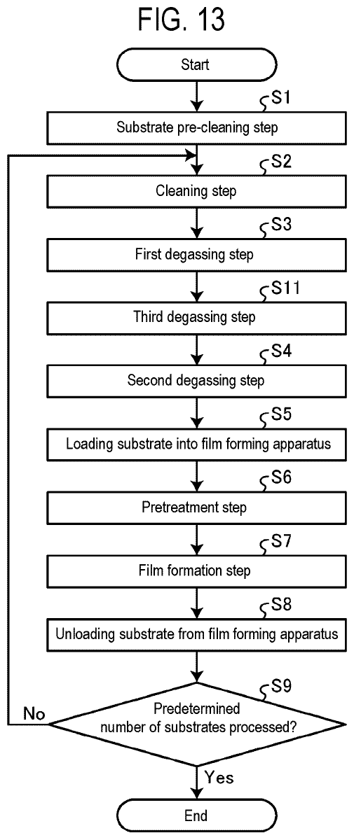

FIG. 13 is a flowchart illustrating an example of a film forming method in Modification 1. In the following description, the processing of steps S1 to S9 of film formation is the same as in the embodiment, and thus, will not be described.

The controller 11 executes the following processing after the first degassing step (step S3). After completion of the first degassing step, the controller 11 executes a third degassing step using a species different from that used in the first degassing step (step S11). The controller 11 controls the gas supplier 163 to supply a second reactive gas from the plurality of discharge ports 167 to the chamber 101. Further, the controller 11 controls the exhauster 105 to control the internal pressure of the chamber 101 to a predetermined pressure (e.g., 50 mTorr to 1 Torr). As the second reactive gas in the third degassing step, for example, an H₂ gas, N₂ gas, or a mixed gas of these, or a mixed gas of these with an Ar gas may be used. Further, another noble gas such as He gas may be used instead of an Ar gas. In addition, the flow rate ratio of the H₂ gas to the N₂ gas in the second reactive gas may be, for example, 1:1000 to 1000:1. Further, the flow rate ratio of the second reactive gas to the noble gas in the third degassing step may be, for example, 1:1000 to 1000:1. Furthermore, as combinations of the first reactive gas in the first degassing step and the second reactive gas in the third degassing step, for example, combinations of an N₂ gas and H₂ gas, of an N₂ gas and N₂/H₂ mixed gas, and of an N₂/H₂ mixed gas and H₂ gas may be mentioned. In addition, in each combination, a mixed gas with an Ar gas may be used. In other words, the third degassing step is a process that extracts and removes nitrogen from the interior of the chamber 101. Further, in addition to the second reactive gas, an additive gas may also be supplied in the third degassing step. As the additive gas in the third degassing step, for example, an oxygen (O₂) gas may be used. The flow rate ratio of the second reactive gas to the additive gas in the third degassing step may be, for example, 1:1 to 5000:1.

The controller 11 controls the microwave introducer 103 to ignite plasma by microwaves with a predetermined power (e.g., 100 W to 2500 W). The controller 11 executes the third degassing step using plasma of the second reactive gas for a predetermined time (e.g., 30 seconds to 180 seconds). In the third degassing step, nitrogen components such as N₂ and NH remaining in the chamber 101 are chemically discharged. Further, by supplying the additive gas together with the second reactive gas, excessive reduction that may generate aluminum (Al) or yttrium (Y) from a protective film can be prevented, and physicochemical etching can be prevented, thereby preventing the occurrence of metal contamination. In addition, the dummy wafer may be omitted in the third degassing step. The controller 11 proceeds to step S4 for the second degassing step after step S11. In this way, Modification 1 may further prevent both the generation of particles and variations in film thickness uniformity between substrates during cumulative film formation.

As described above, according to the present embodiment, a film forming method is a film forming method of forming a carbon film, and includes a) cleaning an interior of a processing container (chamber 101) using plasma generated by supplying an oxygen-containing gas, in a state where the substrate W is not present in the processing container, b) performing a first degassing in the interior of the processing container using plasma generated by supplying a first reactive gas, in a state where the substrate W is not present in the processing container, c) performing a second degassing in the interior of the processing container using plasma generated by supplying a noble gas, in a state where the substrate W is not present in the processing container, d) loading the substrate W into the processing container, e) forming the carbon film on the substrate W using plasma generated by supplying a carbon-containing gas, and f) repeating a) to e) in this order. As a result, it is possible to prevent both the generation of particles and variations in film thickness uniformity between the substrates W during cumulative film formation.

Further, according to the present embodiment, the first reactive gas is at least one of an H₂ gas and N₂ gas. As a result, it is possible to remove residual oxygen within the chamber 101.

Further, according to the present embodiment, the first reactive gas is an H₂ gas and N₂ gas. As a result, it is possible to more rapidly remove residual oxygen from the interior of the chamber 101.

Further, according to the present embodiment, a flow rate ratio between the H₂ gas to the N₂ gas is 1:1000 to 1000:1. As a result, it is possible to more rapidly remove residual oxygen from the interior of the chamber 101.

Further, according to the present embodiment, the first reactive gas further includes an additive gas. As a result, it is possible to prevent the occurrence of metal contamination.

Further, according to the present embodiment, a flow rate ratio of the first reactive gas to the additive gas is 1:1 to 5000:1. As a result, it is possible to prevent the occurrence of metal contamination.

Further, according to the present embodiment, in b), the first degassing is performed in the interior of the processing container using plasma generated by supplying the first reactive gas and the noble gas. As a result, it is possible to prevent both the generation of particles and variations in film thickness uniformity between the substrates W during cumulative film formation.

Further, according to the present embodiment, a flow rate ratio of the first reactive gas to the noble gas is 1:1000 to 1000:1. As a result, it is possible to prevent both the generation of particles and variations in film thickness uniformity between the substrates W during cumulative film formation.

Further, according to the present embodiment, the first degassing is a process that extracts and removes oxygen from the interior of the processing container, and the second degassing is a process that extracts and removes nitrogen from the interior of the processing container. As a result, it is possible to prevent both the generation of particles and variations in film thickness uniformity between the substrates W during cumulative film formation.

Further, according to Modification 1, the film forming method includes g) performing a third degassing in the interior of the processing container using plasma generated by supplying a second reactive gas in a state where the substrate W is not present in the processing container, and g) is executed after b). As a result, it is possible to further prevent both the generation of particles and variations in film thickness uniformity between substrates during cumulative film formation.

Further, according to modification 1, the second reactive gas is at least one of an H₂ gas and N₂ gas. As a result, it is possible to remove nitrogen from the interior of the chamber 101.

Further, according to Modification 1, the second reactive gas is an H₂ gas and N₂ gas. As a result, it is possible to more rapidly remove nitrogen from the interior of the chamber 101.

Further, according to Modification 1, a flow rate ratio of the H₂ gas to the N₂ gas is 1:1000 to 1000:1. As a result, it is possible to more rapidly remove nitrogen from the interior of the chamber 101.

Further, according to Modification 1, the second reactive gas further includes an additive gas. As a result, it is possible to prevent the occurrence of metal contamination.

Further, according to Modification 1, a flow rate ratio of the second reactive gas to the additive gas is 1:1 to 5000:1. As a result, it is possible to prevent the occurrence of metal contamination.

Further, according to Modification 1, in g), the third degassing is performed in the interior of the processing container using plasma generated by supplying the second reactive gas and the noble gas. As a result, it is possible to further prevent both the generation of particles and variations in film thickness uniformity between substrates during cumulative film formation.

Further, according to Modification 1, a flow rate ratio of the second reactive gas to the noble gas is 1:1000 to 1000:1. As a result, it is possible to further prevent both the generation of particles and variations in film thickness uniformity between substrates during cumulative film formation.

Further, according to Modification 1, the third degassing is a process that extracts and removes nitrogen from the interior of the processing container. As a result, it is possible to remove nitrogen from the interior of the chamber 101.

Further, according to the present embodiment and Modification 1, the noble gas is an He gas or Ar gas. As a result, it is possible to prevent both the generation of particles and variations in film thickness uniformity between the substrates W during cumulative film formation.

Further, according to the present embodiment and Modification 1, the oxygen-containing gas is at least one of an O₂ gas, CO gas, and CO₂ gas. As a result, it is possible to remove a carbon film adhered to the inner wall of the chamber 101.

Further, according to the present embodiment and Modification 1, in a), the interior of the processing container is cleaned using plasma generated by supplying the oxygen-containing gas and the noble gas. As a result, it is possible to remove carbon from the interior of the chamber 101.

Further, according to the present embodiment and Modification 1, in e), the carbon film is formed on the substrate W by microwave plasma CVD. As a result, it is possible to form the carbon film while preventing variations in film thickness uniformity between the substrates W during cumulative film formation.

Further, according to the present embodiment and Modification 1, e) includes supplying an additive gas together with the carbon-containing gas. As a result, it is possible to reduce the film thickness of an interfacial oxide film (natural oxide film) formed on the surface of the substrate W and to increase the film thickness of the carbon film.

Further, according to the present embodiment and Modification 1, a flow rate ratio of the carbon-containing reactive gas to the additive gas is 25:1 to 1000:1. As a result, it is possible to reduce the film thickness of an interfacial oxide film (natural oxide film) formed on the surface of the substrate W and to increase the film thickness of the carbon film.

Further, according to the present embodiment and Modification 1, the additive gas is an oxygen gas. As a result, it is possible to prevent the occurrence of metal contamination. Further, it is possible to reduce the film thickness of an interfacial oxide film (natural oxide film) formed on the surface of the substrate W and to increase the film thickness of the carbon film.

Further, according to the present embodiment and Modification 1, the carbon film is a graphene film. As a result, it is possible to form a graphene film while preventing variations in film thickness uniformity between the substrates W during cumulative film formation.

The embodiments disclosed herein should be considered to be exemplary and not limitative in all respects. The above embodiments may be omitted, replaced or modified in various ways without departing from the scope or spirit of the appended claims.

Further, the above-described embodiments have described the film forming apparatuses 1 that performs processing such as etching or film formation on the substrate W using microwave plasma as a plasma source by way of example, but the technique of the disclosure is not limited thereto. The plasma source is not limited to microwave plasma as long as the apparatus performs processing on the substrate W using plasma, and any plasma source such as capacitively coupled plasma, inductively coupled plasma, or magnetron plasma may be used.

According to the present disclosure, it is possible to prevent both the generation of particles and variation in film thickness uniformity between substrates during cumulative film formation.

Further, the present disclosure may also take the following configuration.

(1) A film forming method of forming a carbon film, the method comprising:
a) cleaning an interior of a processing container using plasma generated by supplying an oxygen-containing gas, in a state where a substrate is not present in the processing container;
b) performing a first degassing in the interior of the processing container using plasma generated by supplying a first reactive gas, in a state where the substrate is not present in the processing container;
c) performing a second degassing in the interior of the processing container using plasma generated by supplying a noble gas, in a state where the substrate is not present in the processing container;
d) loading the substrate into the processing container;
e) forming the carbon film on the substrate using plasma generated by supplying a carbon-containing gas; and
f) repeating a) to e) in this order.

(2) The film forming method of (1), wherein the first reactive gas is at least one of an H₂ gas and N₂ gas.

(3) The film forming method of (1), wherein the first reactive gas is an H₂ gas and N₂ gas.

(4) The film forming method of (3), wherein a flow rate ratio of the H₂ gas to the N₂ gas is 1:1000 to 1000:1.

(5) The film forming method of any one of (1) to (4), wherein the first reactive gas further includes an additive gas.

(6) The film forming method of (5), wherein a flow rate ratio of the first reactive gas to the additive gas is 1:1 to 5000:1.

(7) The film forming method of any one of (1) to (6), wherein in b), the first degassing is performed in the interior of the processing container using plasma generated by supplying the first reactive gas and the noble gas.

(8) The film forming method of (7), wherein a flow rate ratio of the first reactive gas to the noble gas is 1:1000 to 1000:1.

(9) The film forming method of any one of (1) to (8), wherein the first degassing is a process that extracts and removes oxygen from the interior of the processing container, and wherein the second degassing is a process that extracts and removes nitrogen from the interior of the processing container.

(10) The film forming method of any one of (1) to (9), further comprising g) performing a third degassing in the interior of the processing container using plasma generated by supplying a second reactive gas, in a state where the substrate is not present in the processing container, wherein g) is executed after b).

(11) The film forming method of (10), wherein the second reactive gas is at least one of an H₂ gas and N₂ gas.

(12) The film forming method of (10), wherein the second reactive gas is an H₂ gas and N₂ gas.

(13) The film forming method of (12), wherein a flow rate ratio of the H₂ gas to the N₂ gas is 1:1000 to 1000:1.

(14) The film forming method of any one of (10) to (13), wherein the second reactive gas further includes an additive gas.

(15) The film forming method of (14), wherein a flow rate ratio of the second reactive gas to the additive gas is 1:1 to 5000:1.

(16) The film forming method of any one of (10) to (15), wherein in g), the third degassing is performed in the interior of the processing container using plasma generated by supplying the second reactive gas and the noble gas.

(17) The film forming method of (16), wherein a flow rate ratio of the second reactive gas to the noble gas is 1:1000 to 1000:1.

(18) The film forming method of any one of (10) to (17), wherein the third degassing is a process that extracts and removes nitrogen from the interior of the processing container.

(19) The film forming method of any one of (1) to (18), wherein the noble gas is an He gas or Ar gas.

(20) The film forming method of any one of (1) to (19), wherein the oxygen-containing gas is at least one of an O₂ gas, CO gas, and CO₂ gas.

(21) The film forming method of any one of (1) to (20), wherein in a), the interior of the processing container is cleaned using plasma generated by supplying the oxygen-containing gas and the noble gas.

(22) The film forming method of any one of (1) to (21), wherein in e), the carbon film is formed on the substrate by microwave plasma chemical vapor deposition (CVD).

(23) The film forming method of any one of (1) to (22), wherein e) includes supplying an additive gas together with the carbon-containing gas.

(24) The film forming method of (23), wherein a flow rate ratio of the carbon-containing gas to the additive gas is 25:1 to 1000:1.

(25) The film forming method of any one of (5), (6), (14), (15), (23), or (24), wherein the additive gas is an oxygen gas.

(26) The film forming method of any one of (1) to (25), wherein the carbon film is a graphene film.

(27) A substrate processing apparatus comprising:
a processing container capable of accommodating a substrate;
a stage capable of placing the substrate thereon;
a plasma source configured to generate plasma within the processing container;
a gas supply source configured to supply a gas into the processing container; and
a controller,
wherein a) the controller is configured to control the substrate processing apparatus, so as to clean an interior of the processing container using plasma, generated by an oxygen-containing gas supplied from the gas supply source and power supplied from the plasma source, in a state where the substrate is not present in the processing container,
b) the controller is configured to control the substrate processing apparatus, so as to perform a first degassing in the interior of the processing container using plasma, generated by a first reactive gas supplied from the gas supply source and power supplied from the plasma source, in a state where the substrate is not present in the processing container,
c) the controller is configured to control the substrate processing apparatus, so as to perform a second degassing in the interior of the processing container using plasma, generated by a noble gas supplied from the gas supply source and power supplied from the plasma source, in a state where the substrate is not present in the processing container,
d) the controller is configured to control the substrate processing apparatus, so as to load the substrate into the processing container and place the substrate on the stage,
e) the controller is configured to control the substrate processing apparatus, so as to form a carbon film on the substrate using plasma, generated by a carbon-containing gas supplied from the gas supply source and power supplied from the plasma source, and
f) the controller is configured to control the substrate processing apparatus, so as to repeat a) to e) in this order.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film forming method of forming a carbon film, the method comprising:
a) cleaning an interior of a processing container using plasma generated by supplying an oxygen-containing gas, in a state where a substrate is not present in the processing container;
b) performing a first degassing in the interior of the processing container using plasma generated by supplying a first reactive gas, in a state where the substrate is not present in the processing container;
c) performing a second degassing in the interior of the processing container using plasma generated by supplying a noble gas, in a state where the substrate is not present in the processing container;
d) loading the substrate into the processing container;
e) forming the carbon film on the substrate using plasma generated by supplying a carbon-containing gas; and
f) repeating a) to e) in this order.

2. The film forming method of claim 1, wherein the first reactive gas is at least one of an H₂ gas and N₂ gas.

3. The film forming method of claim 1, wherein the first reactive gas is an H₂ gas and N₂ gas.

4. The film forming method of claim 3, wherein a flow rate ratio of the H₂ gas to the N₂ gas is 1:1000 to 1000:1.

5. The film forming method of claim 1, wherein the first reactive gas further includes an additive gas.

6. The film forming method of claim 5, wherein a flow rate ratio of the first reactive gas to the additive gas is 1:1 to 5000:1.

7. The film forming method of claim 1, wherein in b), the first degassing is performed in the interior of the processing container using plasma generated by supplying the first reactive gas and the noble gas.

8. The film forming method of claim 7, wherein a flow rate ratio of the first reactive gas to the noble gas is 1:1000 to 1000:1.

9. The film forming method of claim 1, wherein the first degassing is a process that extracts and removes oxygen from the interior of the processing container, and
wherein the second degassing is a process that extracts and removes nitrogen from the interior of the processing container.

10. The film forming method of claim 1, further comprising g) performing a third degassing in the interior of the processing container using plasma generated by supplying a second reactive gas, in a state where the substrate is not present in the processing container,
Wherein g) is executed after b).

11. The film forming method of claim 10, wherein the second reactive gas is at least one of an H₂ gas and N₂ gas.

12. The film forming method of claim 10, wherein the second reactive gas is an H₂ gas and N₂ gas.

13. The film forming method of claim 12, wherein a flow rate ratio of the H₂ gas to the N₂ gas is 1:1000 to 1000:1.

14. The film forming method of claim 10, wherein the second reactive gas further includes an additive gas.

15. The film forming method of claim 14, wherein a flow rate ratio of the second reactive gas to the additive gas is 1:1 to 5000:1.

16. The film forming method of claim 10, wherein in g), the third degassing is performed in the interior of the processing container using plasma generated by supplying the second reactive gas and the noble gas.

17. The film forming method of claim 16, wherein a flow rate ratio of the second reactive gas to the noble gas is 1:1000 to 1000:1.

18. The film forming method of claim 10, wherein the third degassing is a process that extracts and removes nitrogen from the interior of the processing container.

19. The film forming method of claim 1, wherein the noble gas is an He gas or Ar gas.

20. The film forming method of claim 1, wherein the oxygen-containing gas is at least one of an O₂ gas, CO gas, and CO₂ gas.

21. The film forming method of claim 1, wherein in a), the interior of the processing container is cleaned using plasma generated by supplying the oxygen-containing gas and the noble gas.

22. The film forming method of claim 1, wherein in e), the carbon film is formed on the substrate by microwave plasma chemical vapor deposition (CVD).

23. The film forming method of claim 1, wherein e) includes supplying an additive gas together with the carbon-containing gas.

24. The film forming method of claim 23, wherein a flow rate ratio of the carbon-containing gas to the additive gas is 25:1 to 1000:1.

25. The film forming method of claim 5, wherein the additive gas is an oxygen gas.

26. The film forming method of claim 1, wherein the carbon film is a graphene film.

27. A substrate processing apparatus comprising:
a processing container capable of accommodating a substrate;
a stage capable of placing the substrate thereon;
a plasma source configured to generate plasma within the processing container;
a gas supply source configured to supply a gas into the processing container; and
a controller,
wherein a) the controller is configured to control the substrate processing apparatus, so as to clean an interior of the processing container using plasma, generated by an oxygen-containing gas supplied from the gas supply source and power supplied from the plasma source, in a state where the substrate is not present in the processing container,
b) the controller is configured to control the substrate processing apparatus, so as to perform a first degassing in the interior of the processing container using plasma, generated by a first reactive gas supplied from the gas supply source and power supplied from the plasma source, in a state where the substrate is not present in the processing container,
c) the controller is configured to control the substrate processing apparatus, so as to perform a second degassing in the interior of the processing container using plasma, generated by a noble gas supplied from the gas supply source and power supplied from the plasma source, in a state where the substrate is not present in the processing container,
d) the controller is configured to control the substrate processing apparatus, so as to load the substrate into the processing container and place the substrate on the stage,
e) the controller is configured to control the substrate processing apparatus, so as to form a carbon film on the substrate using plasma, generated by a carbon-containing gas supplied from the gas supply source and power supplied from the plasma source, and
f) the controller is configured to control the substrate processing apparatus, so as to repeat a) to e) in this order.
